(19) United States
(12) Patent Application Publication
(10) Pub. No.: US 2025/0015234 A1
(43) Pub. Date: Jan. 9, 2025

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventors: Rainer Hartmann, Regensburg (DE); Benjamin Michaelis, Regensburg (DE); Anna Kasprzak-Zablocka, Donaustauf (DE); Björn Grootoonk, Donaustauf (DE); Isabel Otto, Regenstauf (DE); Dominik Scholz, Bad Abbach (DE)

(21) Appl. No.: 18/709,402

(22) PCT Filed: Nov. 10, 2022
(86) PCT No.: PCT/EP2022/081401

§ 371 Date: May 10, 2024

(30) Foreign Application Priority Data
Nov. 18, 2021 (DE) 10 2021 130 159.9

(51) Int. Cl. H01L 33/44; H01L 31/0216; H01L 31/0224; H01L 31/0232; H01L 31/0352; H01L 33/24; H01L 33/38; H01L 33/40

(52) U.S. Cl. CPC H01L 33/44; H01L 31/02161; H01L 31/022408; H01L 31/02327; H01L 31/035281; H01L 33/24; H01L 33/38; H01L 33/405; H01L 2933/0025

(57) ABSTRACT

In an embodiment, an optoelectronic component includes a structured region including a semiconductor body having a first semiconductor region and a second semiconductor region, which have different conductivities, a first main surface and a second main surface and at least one first delimiting surface and at least one second delimiting surface delimiting a recess, a protective layer, which is arranged on the at least one first delimiting surface and covers a junction between the first semiconductor region and the second semiconductor region in the recess, wherein the first main surface is not covered by the protective layer and the protective layer does not adjoin any further protective layer on a side facing the junction and on a side facing away from the junction, and wherein the protective layer is retracted from the first delimiting surface and the second delimiting surface or wherein the protective layer has an L-shape in cross-section.

### CROSS-REFERENCE TO RELATED APPLICATIONS

This patent application is a national phase filing under section 371 of PCT/EP2022/081401, filed Nov. 10, 2022, which claims the priority of German patent application 102021130159.9, filed Nov. 18, 2021, each of which is incorporated herein by reference in its entirety.

### TECHNICAL FIELD

An optoelectronic component and a method for producing an optoelectronic component are specified herein. For example, the optoelectronic component is suitable for emitting electromagnetic radiation, for example in the visible to infrared spectral range.

### BACKGROUND

Various methods such as photolithography or so-called spacer technology, in which a spacer layer is structured in a self-adjusting manner, are used for structuring layers, for example passivation layers, in optoelectronic components. Spacer technology is used in particular at step-like junctions of semiconductor layer sequences of optoelectronic components. While photolithography is relatively cost-intensive, for spacer technology only a limited selection of so-called spacer materials, for example TEOS (tetraethyl orthosilicate), can be used with which the necessary requirements, such as conformal edge coverage and sufficient layer thickness at an acceptable growth rate, can be met. While a relatively thick spacer layer is desirable during processing, a spacer produced from it takes up a relatively large amount of space in the finished component, which is lost, for example, as a contact area for electrical connections, which can lead to higher contact resistance and reduced performance of the optoelectronic components.

### SUMMARY

Embodiments provide a high-performance optoelectronic component. Further embodiments provide an efficient method for producing such an optoelectronic component.

According to at least one embodiment of an optoelectronic component, the optoelectronic component comprises a structured region.

The structured region may include a semiconductor body comprising a first semiconductor region and a second semiconductor region, which have different conductivities. For example, the semiconductor body may have an active zone between the first and second semiconductor regions, the active zone being provided for receiving or generating electromagnetic radiation. In particular, the optoelectronic component is a radiation-emitting component. The semiconductor body can be structured, having a structuring corresponding to the structured region.

The first and second semiconductor regions and the active zone can each be formed from one or more semiconductor layers. The semiconductor layers can be layers epitaxially deposited on a growth substrate. The growth substrate can remain in the semiconductor body after the semiconductor layers have grown or can be at least partially removed.

Materials based on arsenide, phosphide or nitride compound semiconductors, for example, can be considered for the semiconductor regions or semiconductor layers of the semiconductor body. “Based on arsenide, phosphide or nitride compound semiconductors” in the present context means that the semiconductor layers contain AlₙGaₘIn₁₋ₙ₋ₘAs, AlₙGaₘIn₁₋ₙ₋ₘP or AlₙGaₘIn₁₋ₙ₋ₘN, with 0≤n≤1, 0≤m≤1 and n+m≤1. This material does not necessarily have to have a mathematically exact composition according to the above formula. Rather, it can include one or more dopants as well as additional constituents that essentially do not change the characteristic physical properties of the AlₙGaₘIn₁₋ₙ₋ₘAs, AlₙGaₘIn₁₋ₙ₋ₘP or AlₙGaₘIn₁₋ₙ₋ₘN material. For the sake of simplicity, however, the above formula only contains the essential constituents of the crystal lattice (Al, Ga, In, As or P or N), even if these may be partially replaced by small amounts of other substances.

Furthermore, the structured region may have a first main surface and a second main surface, which delimit the structured region on two opposite sides, for example. The first semiconductor region can be arranged on a side of the second semiconductor region facing the first main surface, and the second semiconductor region can be arranged on a side of the first semiconductor region facing the second main surface.

The structured region can have at least one structured layer that is arranged on the semiconductor body. This may, for example, be a contact layer, a reflective layer or a dielectric layer. The at least one structured layer can be arranged on a surface of the semiconductor body facing the first main surface.

Furthermore, the structured region may have at least one first delimiting surface and at least one second delimiting surface, wherein the at least one first delimiting surface laterally delimits a recess extending from the first main surface into the structured region, and the at least one second delimiting surface delimits the recess on a side facing the second main surface. The recess may be open on one or more sides. Alternatively, the recess may be closed on all sides. In other words, the recess may be partially or completely delimited laterally by one or more first delimiting surfaces.

In the present case, a recess means, for example, a space between a raised partial region and a lower partial region of the structured region.

For example, the second delimiting surface can be formed by a surface of the second semiconductor region of the semiconductor body. The surface can be arranged essentially parallel to the second main surface, i.e. within the usual manufacturing tolerances. Furthermore, at least a part of the first delimiting surface can be formed by a surface of the semiconductor body arranged transversely to the first and/or second main surface.

Further, the optoelectronic component may comprise an electrically weakly conductive or non-conductive protective layer arranged on the at least one first delimiting surface and covering a junction between the first semiconductor region and the second semiconductor region in the recess. The protective layer may be provided to electrically insulate a p-n junction, for example present in the active zone, from the environment. For example, the protective layer can serve as a spacer between the junction or the active zone and an electrical contact means of the optoelectronic component. The protective layer can be arranged on all first delimiting surfaces that laterally delimit the recess.

Furthermore, the first main surface of the structured region can be uncovered by the protective layer. An initial layer used to produce the protective layer can first be applied to the first main surface and then structured so that it no longer covers the first main surface.

According to at least one embodiment, the optoelectronic component comprises
a structured region comprising
a semiconductor body comprising a first semiconductor region and a second semiconductor region, which have different conductivities,
a first main surface and a second main surface,
at least one first delimiting surface and at least one second delimiting surface, wherein the at least one first delimiting surface laterally delimits a recess extending from the first main surface into the structured region, and the at least one second delimiting surface delimits the recess on a side facing the second main surface, and
an electrically weakly conductive or non-conductive protective layer, which is arranged on the at least one first delimiting surface and covers a junction between the first semiconductor region and the second semiconductor region in the recess, wherein
the first main surface is uncovered by the protective layer.

According to at least one embodiment or configuration, the protective layer is a layer conformally deposited on the structured region. In the case of conformal deposition, layer growth on vertical edges is just as high as on horizontal surfaces. A conformally deposited layer can therefore have a constant thickness. For example, the thickness of the protective layer can be relatively small compared to spacer layers and can be between a few nanometers and a few hundred nanometers.

According to at least one embodiment or configuration, the protective layer contains an oxide or nitride. For example, the protective layer may contain at least one of the following materials: Al2O3, Ta2O5, HfO2, SiO2, SiN, AlN. The protective layer can be multilayered and contain a combination of the materials mentioned. Such materials are characterized, for example, by their passivation properties. Advantageously, the materials used for the protective layer can be selected relatively freely based on the method described herein.

According to at least one embodiment or configuration, the protective layer is retracted from the first main surface and has a vertical distance from a plane of the first main surface that is greater than or equal to zero. The vertical distance is determined along a vertical direction that is transverse to a main extension plane of the structured region.

Furthermore, the protective layer can extend from the at least one first delimiting surface to or onto the second delimiting surface and have a vertical distance from the second delimiting surface which is essentially zero, i.e. within the scope of usual manufacturing tolerances. Here, regions of the first delimiting surface arranged between the junction between the semiconductor regions and the second delimiting surface can be at least largely covered by the protective layer.

Alternatively, the protective layer can be retracted from the second delimiting surface and have a vertical distance therefrom which is greater than zero. In this case, the at least one first delimiting surface can be largely uncovered by the protective layer. For example, the protective layer can be delimited to the junction between the semiconductor regions.

According to at least one embodiment or configuration, the protective layer has an opening region at the second delimiting surface, in which the second delimiting surface is uncovered by the protective layer. The uncovered region of the second delimiting surface can form a contact area of the semiconductor body.

According to at least one embodiment or configuration, the optoelectronic component comprises an electrical contact means which is arranged in the opening region of the protective layer. The electrical contact means can extend from the first main surface of the structured region through the recess to the second delimiting surface and form a second electrode of the optoelectronic component.

According to at least one embodiment or configuration, the optoelectronic component comprises a further electrical contact means arranged at the first main surface. For example, the further electrical contact means may be arranged on a side of the semiconductor body facing the first main surface and form a first electrode of the optoelectronic component. The two electrical contact means or the first and second electrodes can be electrically insulated from each other by an insulating layer.

According to at least one embodiment or configuration, the optoelectronic component comprises a further protective layer, which is arranged on the protective layer and has a greater thickness than the protective layer arranged underneath. The further protective layer may contain an oxide, for example SiO₂, or nitride, for example SiNx. Furthermore, the further protective layer can be a conformally deposited layer. The thickness of the further protective layer can be between 200 nm and 10 μm, in particular between 400 nm and 2 μm. The further protective layer can be produced using CVD (chemical vapor deposition) or PECVD (plasma-enhanced CVD). The further protective layer, together with the protective layer on which it is arranged, can serve as a spacer between the junction between the semiconductor regions and the electrical contact means arranged in the recess.

The method described below is suitable for producing an optoelectronic component of the above-mentioned type. Features described in connection with the optoelectronic component therefore also apply to the method and vice versa.

According to at least one embodiment of a method for producing an optoelectronic component of the above-mentioned type, the method comprises:
Providing a structured region comprising
a semiconductor body comprising a first semiconductor region and a second semiconductor region, which have different conductivities,
a first main surface and a second main surface,
at least one first delimiting surface and at least one second delimiting surface, wherein the at least one first delimiting surface laterally delimits a recess extending from the first main surface into the structured region, and the at least one second delimiting surface delimits the recess on a side facing the second main surface,
generating a first initial layer for producing an electrically weakly conductive or non-conductive protective layer on the first main surface, the first delimiting surface and the second delimiting surface,
generating a second initial layer on the first initial layer for producing a further protective layer,
producing a structured second initial layer, wherein regions of the second initial layer which are arranged on the first main surface and regions which are arranged on the second delimiting surface are removed, and
structuring the first initial layer by means of the structured second initial layer, wherein regions which are uncovered by the structured second initial layer are removed.

The structured, second initial layer therefore has the function of a mask layer, in particular the function of an etching mask. This means that no photolithographic processes are required for structuring the first initial layer.

Furthermore, the structured second initial layer can be completely removed and thus serve as a sacrificial layer. Due to the function of the structured second initial layer as a mask or sacrificial layer, a surface of the first initial layer covered by the structured second initial layer is advantageously less attacked during structuring, so that the protective layer has a lower surface roughness, which has a positive effect on the reflective properties of reflective means arranged thereon and thus on the brightness of the component.

According to at least one embodiment or configuration, the second initial layer is produced thicker than the first initial layer. The second initial layer can be structured by means of an anisotropic etching process. For example, the second initial layer can be structured in a self-adjusting manner by anisotropic back-etching. “In a self-adjusting manner” in the present context means in particular that no lithographic processes are used for structuring. A layer or etch removal can correspond to the thickness of the second initial layer. For example, the second initial layer can be produced from SiO₂ or SiNx by chemical vapor deposition, for example by CVD or PECVD. This allows a relatively conformal layer to be generated at an acceptable deposition rate.

According to at least one embodiment or configuration, the first initial layer is produced by one of the following methods: ALD (atomic layer deposition), PECVD (plasma-enhanced chemical vapor deposition), sputtering. Using these methods, it is possible to deposit the first initial layer conformally with a comparatively low thickness. It is possible to apply several first initial layers to the structured region to produce one or more protective layers. Advantageously, the materials used can be selected relatively freely. In particular, materials based on an oxide or nitride such as Al2O3, Ta2O5, HfO2, SiO2, SiN or AlN can be considered for the first initial layer.

According to at least one embodiment or configuration, the first initial layer is structured using a dry-chemical etching process. In this process, the first initial layer is etched selectively to the structured second initial layer. The structured first initial layer can be flush with the structured second initial layer. In other words, the first initial layer can be removed except for a region covered by the structured second initial layer.

Alternatively, the first initial layer can be structured using a wet-chemical etching process. This requires sufficient etching selectivity between the first initial layer and the second initial layer. The wet-chemical etching process is a gentler method than the dry-chemical etching process, as the etched material is less damaged. The structured second initial layer can be underetched. In other words, the first initial layer can also be removed in areas covered by the structured second initial layer.

According to at least one embodiment, the structured second initial layer is removed after structuring of the first initial layer. This can be done, for example, by a wet-chemical etching process, in particular selectively to the structured first initial layer.

### BRIEF DESCRIPTION OF THE DRAWINGS

Further advantages, advantageous embodiments and further developments will become apparent from the exemplary embodiments described below in conjunction with the figures.

FIGS. 1A to 1C show various steps of a method for producing an optoelectronic component according to a comparative example;

FIGS. 2A to 2E show various steps of a method for producing an optoelectronic component according to a first exemplary embodiment;

FIGS. 2A to 2C and 3A to 3C show various steps of a method for producing an optoelectronic component according to a second exemplary embodiment;

FIGS. 2A to 2C and 4A to 4C show various steps of a method for producing an optoelectronic component according to a third exemplary embodiment;

FIGS. 5A and 5B, FIGS. 5A and 5C and FIGS. 5A and 5D each show various steps of a method for producing an optoelectronic component according to further exemplary embodiments;

FIG. 6A shows a schematic cross-sectional view of a structured region with a structured layer according to a comparative example, and FIGS. 6B to 6E show schematic cross-sectional views of structured regions each with a protective layer according to various exemplary embodiments;

FIGS. 7 and 9 show schematic cross-sectional views of optoelectronic components according to various exemplary embodiments; and

FIG. 8 shows a schematic cross-sectional view of an optoelectronic component according to a comparative example.

### DETAILED DESCRIPTION OF ILLUSTRATIVE EMBODIMENTS

In the exemplary embodiments and figures, identical, similar or similarly acting elements can each be provided with the same reference signs. The elements shown and their relative sizes are not necessarily to be regarded as true to scale; rather, individual elements may be shown exaggeratedly large for better visualization and/or better understanding.

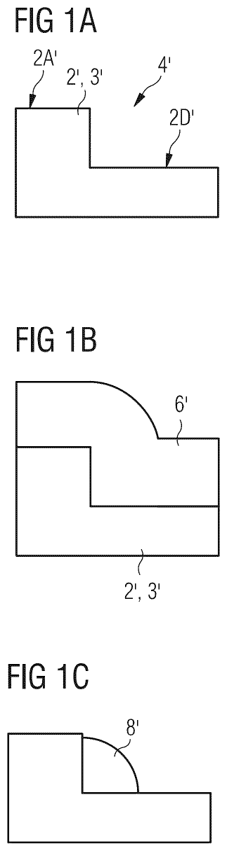

FIGS. 1A to 1C illustrate in more detail a comparative example of a method for producing an optoelectronic component.

First, a structured region 2′ having a structured semiconductor body 3′ is provided. The structured region 2′ has a recess 4′, so that the structured region 2′ has a step-like course from a first main surface 2A′ to a second delimiting surface 2D′ in the schematic cross-sectional view shown in FIG. 1A.

For example, a sufficiently thick initial layer 6′ is generated from TEOS on the structured region 2′ (see FIG. 1B). Other materials are less suitable in terms of conformity and deposition rate.

Furthermore, a so-called spacer 8′ is generated by anisotropic etching of the initial layer 6′ (see FIG. 1C).

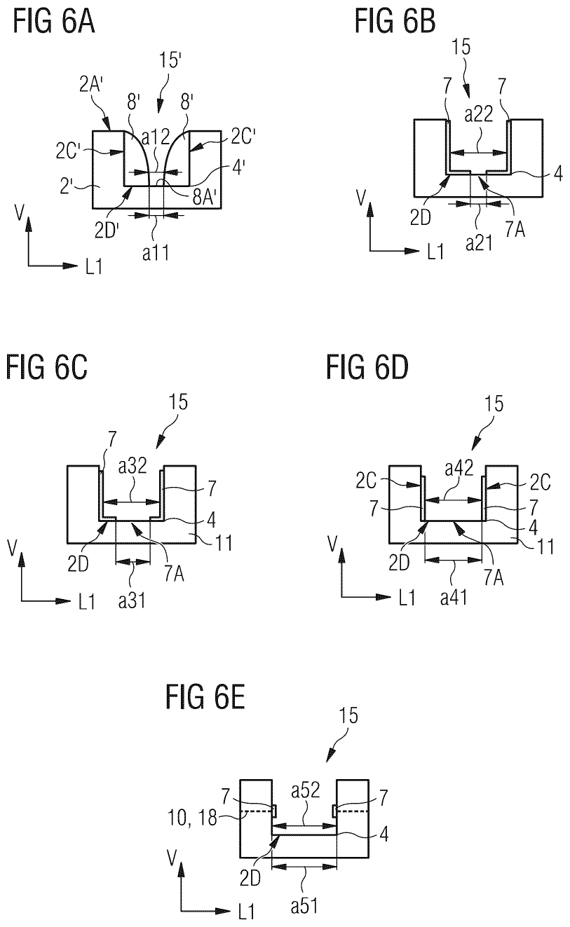

FIG. 6A shows a structured region 2′ with a spacer 8′, which can be produced using a method as described in connection with FIGS. 1A to 1C. As can be seen from FIG. 6A, the spacer 8′ occupies a large part of the recess 4′, so that a contact means arranged in the recess 4′ is laterally constricted. This results, for example, in a higher thermal resistance and contact resistance and a lower current-carrying capacity.

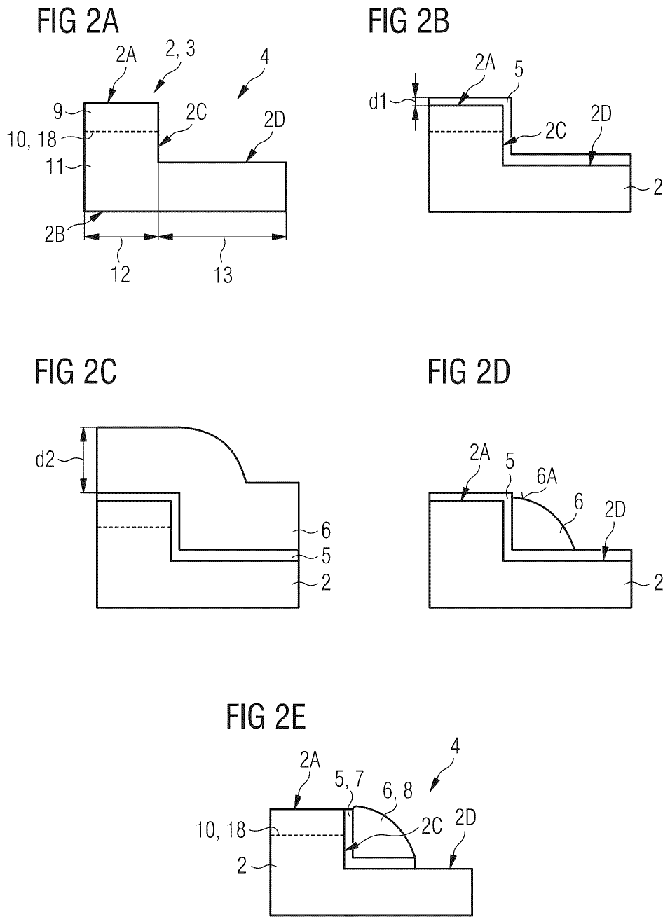

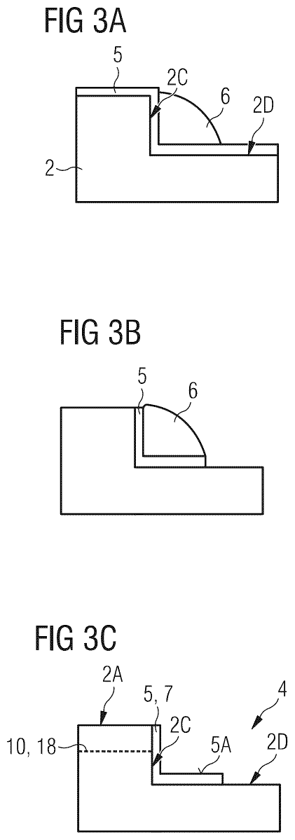

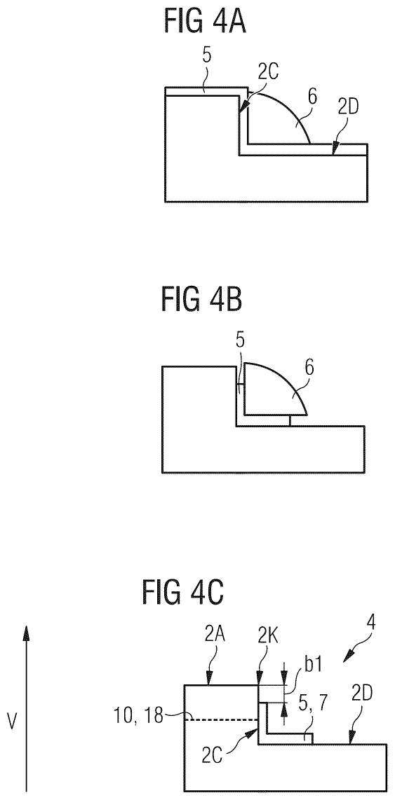

With reference to FIGS. 2A to 2E, a first exemplary embodiment of a method for producing an optoelectronic component is described.

First, a structured region 2 is provided (see FIG. 2A). The structured region 2 comprises or consists of a semiconductor body 3.

The semiconductor body 3 comprises a first semiconductor region 9 of a first conductivity and a second semiconductor region 11 of a second conductivity. An active zone 10 may be arranged at a junction 18 between the first and second semiconductor regions 9, 11, wherein the active zone 10 may be provided for generating or receiving electromagnetic radiation. For example, the first semiconductor region 9 is a p-doped region and the second semiconductor region 11 is an n-doped region.

The first and second semiconductor regions 9, 11 and the active zone 10 can each be formed from one or more semiconductor layers. The semiconductor layers may be layers epitaxially deposited on a growth substrate. The growth substrate can remain in the semiconductor body 3 after the semiconductor layers have grown or can be at least partially removed. For the semiconductor regions 9, 10, 11 or semiconductor layers of the semiconductor body 3, materials based on arsenide, phosphide or nitride compound semiconductors, for example, can be considered, as already explained in more detail above.

Furthermore, the structured region 2 has a first main surface 2A and a second main surface 2B. The first semiconductor region 9 is arranged on a side of the second semiconductor region 11 facing the first main surface 2A, and the second semiconductor region 11 is arranged on a side of the first semiconductor region 9 facing the second main surface 2B.

Furthermore, the structured region 2 has a first delimiting surface 2C and a second delimiting surface 2D, wherein the first delimiting surface 2C laterally delimits a recess 4 extending from the first main surface 2A into the structured region 2, and the second delimiting surface 2D delimits the recess 4 on a side facing the second main surface 2B. At the same time, a raised partial region 12 of the structured region 2 is delimited by the first delimiting surface 2C on a side facing the recess 4. Furthermore, a lower partial region 13 of the structured region 2 is delimited by the first delimiting surface 2C on a side facing the recess 4.

In a further step, a first initial layer 5 for producing an electrically weakly conductive or non-conductive protective layer 7 is generated on the first main surface 2A, the first delimiting surface 2C and the second delimiting surface 2D (see FIGS. 2B and 2E). Advantageously, the first initial layer 5 is deposited conformally on the structured region 2. One of the following methods, for example, can be used to produce the first initial layer 5: ALD, PECVD, sputtering.

In conformal deposition, layer growth on vertical edges, i.e. for example on the first delimiting surface 2C, is just as high as on horizontal surfaces, i.e. for example on the first main surface 2A and the second delimiting surface 2D. The conformally deposited initial layer 5 can therefore have a constant thickness d1, which is between a few nanometers and a few hundred nanometers, for example.

The initial layer 5 can be formed from an oxide such as Al2O3, Ta2O5, HfO2 or SiO2 or a nitride such as SiN or AlN. Advantageously, the materials for the initial layer 5 are relatively freely selectable, since the initial layer 5 does not have to fulfill the requirements for a mask layer or sacrificial layer, which are instead fulfilled by a second initial layer 6 (see FIG. 2C).

In a further step, a second initial layer 6 is generated on the first initial layer 5 to produce a further protective layer 8 (see FIGS. 2C and 2E). The second initial layer 6 can be deposited conformally on the first initial layer 5 with a greater thickness d2 than the first initial layer 5. The thickness d2 can be between 200 nm and 10 μm, in particular between 400 nm and 2 μm. For example, the second initial layer 6 can be produced from SiO₂ or SiNx by chemical vapor deposition, for example by CVD or PECVD.

In a further step, structuring of the second initial layer 6 is performed, wherein regions of the second initial layer 6 arranged on the first main surface 2A and regions arranged on the second delimiting surface 2D are removed (cf. FIG. 2D). The second initial layer 6 can be structured by means of anisotropic back-etching in a self-adjusting manner without the use of photolithographic methods. A layer or etch removal can correspond to the thickness d2 of the second initial layer 6. The structured second initial layer 6 has a convexly curved surface 6A on a side facing away from the structured region 2.

Subsequently, the first initial layer 5 is structured by means of the structured second initial layer 6, wherein regions that are uncovered by the structured second initial layer 6 are removed (see FIG. 2E). The structured second initial layer 6 thus serves as a mask layer, in particular as an etching mask. No photolithographic processes are thus required for structuring the first initial layer 5.

The first initial layer 5 can be structured selectively to the second initial layer 6 by means of a dry-chemical etching process. The structured first initial layer 5 can then be flush with the structured second initial layer 6. In other words, the first initial layer 5 can be removed except for an area covered by the structured, second initial layer 6.

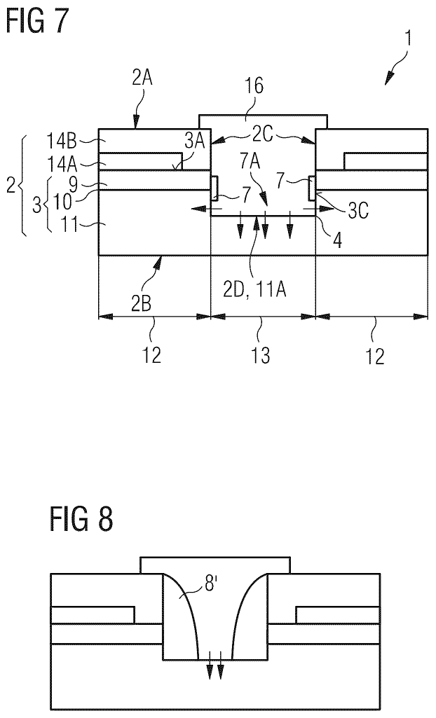

An optoelectronic component produced using this method can have a first protective layer 7 arranged on the first and second delimiting surfaces 2C, 2D which has an L-shape in cross-section and covers the junction 18 between the two semiconductor regions 9, 11 or the active zone 10 in the recess 4, the first main surface 2A being uncovered by the protective layer 7. Here, the first protective layer 7 can be identical to the structured first initial layer 5. Furthermore, the component produced in this way can have a further protective layer 8, which is identical to the structured second initial layer 6. The first and second protective layers 7, 8 can form a spacer between the junction 18 or the active zone 10 and an electrical contact means (see FIGS. 7 and 9). The protective layer 8 may differ from the underlying protective layer 7 in its rupture resistance. The rupture resistance can be lower for the further protective layer 8. The optoelectronic component is characterized by a particularly good rupture resistance and an associated comparatively high performance.

FIGS. 2A to 2C and 3A to 3C are used to describe a further exemplary embodiment of a method for producing an optoelectronic component. The steps shown in FIGS. 2A to 2C have already been explained in more detail above and are therefore not described again.

As shown in FIG. 3A, the second initial layer 6 is structured after deposition, so that the first initial layer 5 is covered by the structured second initial layer 6 only in areas of the first delimiting surface 2C and the second delimiting surface 2D. The step shown in FIG. 3A can be identical to the step shown in FIG. 2D.

In a further step, the first initial layer 5 is structured by means of the structured second initial layer 6, which thus serves as a mask layer, in particular as an etching mask (see FIG. 3B). The structuring can be carried out by means of an anisotropic etching process, for example by means of dry-chemical etching. In this process, the first initial layer 5 can be removed except for an area covered by the structured, second initial layer 6. The step shown in FIG. 3B can be identical to the step shown in FIG. 2E.

In a further step, the structured second initial layer 6 is removed (see FIG. 3C). This can be done, for example, by a wet-chemical etching process, in particular selectively to the structured first initial layer. The initial layer 6 additionally serves as a sacrificial layer here.

Due to the function of the structured second initial layer 6 as a mask or sacrificial layer, a surface 5A of the first initial layer 5 covered by the structured second initial layer is advantageously less attacked during structuring, so that the protective layer 7 has a lower surface roughness, which has a positive effect on the reflective properties of reflective means arranged thereon and thus on the brightness of the component (see also FIG. 9).

An optoelectronic component produced by this method can have a first protective layer 7 arranged on the first and second delimiting surfaces 2C, 2D which has an L-shape in cross-section and covers the junction 18 or the active zone 10 in the recess 4, the first main surface 2A being uncovered by the protective layer 7 and the protective layer 7 being retracted from the first main surface 2A. In this case, the first protective layer 7 can be substantially flush with the first main surface 2A, i.e. within the usual manufacturing tolerances, so that a vertical distance to a plane of the first main surface 2A is zero or tends towards zero. The protective layer 7 can be identical to the structured first initial layer 5. The first protective layer 7 can form a spacer between the p-n junction 18 or between the active zone 10 and an electrical contact means (see FIGS. 7 and 9).

FIGS. 2A to 2C and 4A to 4C are used to describe a further exemplary embodiment of a method for producing an optoelectronic component. The steps shown in FIGS. 2A to 2C have already been explained in more detail above and are therefore not described again.

As shown in FIG. 4A, the second initial layer 6 is structured after deposition so that it is arranged only on the first delimiting surface 2C and the second delimiting surface 2D. The step illustrated in FIG. 4A may be identical to the step illustrated in FIG. 2D and FIG. 3A.

In a further step, the first initial layer 5 is structured by means of the structured second initial layer 6 (see FIG. 4B). The structuring can be carried out selectively to the second initial layer 6 by means of a wet-chemical etching process. In this process, the structured second initial layer 6 can be underetched so that side edges of the structured first initial layer 5 are retracted relative to side edges of the structured second initial layer 6. In other words, the first initial layer 5 can also be removed in areas covered by the structured second initial layer 6. Thus, lateral dimensions of the protective layer 7 are decoupled from the thickness of the second initial layer 6.

In a further step, the structured second initial layer 6 is removed (see FIG. 4C). This can be done, for example, by a wet-chemical etching process. The step shown in FIG. 4C can be identical to the step shown in FIG. 3C.

An optoelectronic component produced by this method can have a first protective layer 7 arranged on the first and second delimiting surfaces 2C, 2D which has an L-shape in cross-section and covers the junction 18 or the active zone 10 in the recess 4, wherein
the first main surface 2A is uncovered by the protective layer 7 and the protective layer 7 is retracted from the first main surface 2A. In this case, the first protective layer 7 can have a vertical distance b1 to a plane 2K of the first main surface 2A, which is specified parallel to a vertical direction V and is greater than zero. The plane 2K is arranged parallel to a main extension plane of the structured region 2, while the vertical direction V is arranged transverse or perpendicular to it. The protective layer 7 can be identical to the structured first initial layer 5. The first protective layer 7 can form a spacer between the junction 18 or the active zone 10 and an electrical contact means (see FIGS. 7 and 9). The optoelectronic component is characterized by an enlarged contact area and an associated comparatively high performance.

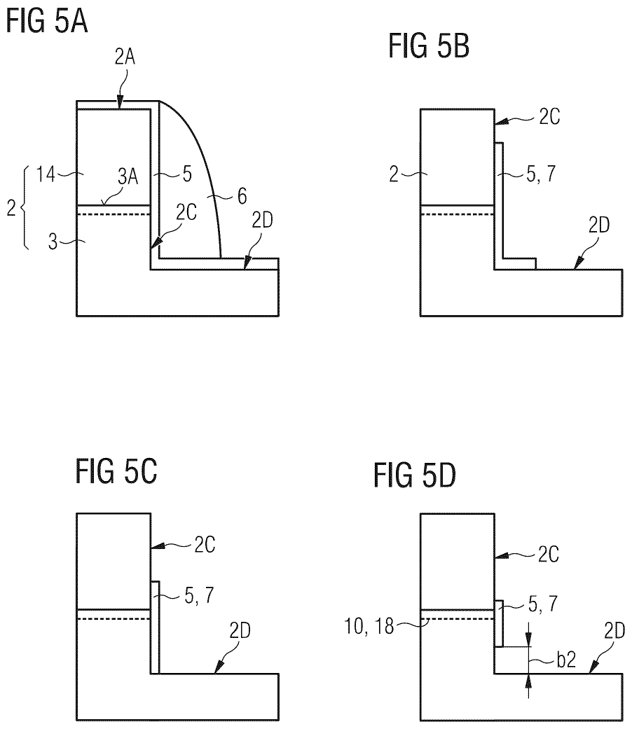

With reference to FIGS. 5A to 5D, further exemplary embodiments of methods for producing optoelectronic components are described.

Here, a structured region 2 is provided, which comprises a structured semiconductor body 3 and at least one structured layer 14, which is arranged on the semiconductor body 3. The at least one structured layer 14 may be, for example, a contact layer, a reflective layer or a dielectric layer. The at least one structured layer 14 is arranged on a surface 3A of the semiconductor body 3 facing the first main surface 2A. Analogous to the steps shown in FIGS. 2A to 2D, a first initial layer 5 is deposited conformally on the structured region 2, and a second initial layer 6 is applied thereto, which is then structured so that it only covers areas of the first initial layer 5 arranged on the first and second delimiting surfaces 2C, 2D.

The further steps are similar to the steps shown in FIGS. 4A to 4C, so that in particular all the explanations and advantages given in connection with FIGS. 4A to 4C retain their validity.

The structured second initial layer 6 is used for structuring the first initial layer 5. The structuring can be carried out, for example, by wet-chemical etching (see FIG. 4B). The expansion of the first initial layer 5 can be changed by the etching time, whereby the first initial layer 5 is retracted from the first main surface 2A and the second delimiting surface 2D to different extents. For example, the L-shape shown in FIG. 5B can be achieved by short etching, the structured first initial layer 5 or protective layer 7 extending from the first delimiting surface 2C to the second delimiting surface 2D. The expansion of the first initial layer 5 can be further reduced by medium etching, so that the structured first initial layer 5 or protective layer 7 only extends to the second delimiting surface 2D (see FIG. 5C). In both cases, the first initial layer 5 or protective layer 7 has a vertical distance from the second delimiting surface 2D that is zero or tends towards zero. Prolonged etching can reduce the expansion of the first initial layer 5 to such an extent that the structured first initial layer 5 or protective layer 7 is retracted from the second delimiting surface 2D and has a vertical distance b2 from the second delimiting surface 2D that is greater than zero, and the structured first initial layer 5 or protective layer 7 is essentially only arranged in the area of the junction 18 or the active zone 10 (see FIG. 5D).

The expansion of the structured first initial layer 5 or the first protective layer 7 is advantageously decoupled from the thickness of the second initial layer 6. The structured first initial layer 5 or first protective layer 7 is generated in a self-adjusting manner without the use of photo technology.

After structuring the first initial layer 5, the second initial layer can be removed in a manner analogous to the step shown in FIG. 4C.

FIGS. 6A to 6E illustrate the relationships between the structural properties and thermal or electrical properties of an optoelectronic component.

In the comparative example shown in FIG. 6A, the structured region 2′ has several first delimiting surfaces 2C′, which laterally delimit the recess 4′. The spacer 8′ is arranged in the recess 4′ and largely fills it except for an intermediate space 15′. The second delimiting surface 2D′ is uncovered by the spacer 8′ in an opening region 8A′ of the spacer 8′. The opening region 8A′ has a lateral dimension a11 parallel to a lateral direction L1. Starting from the opening region 8A′, the lateral dimension of the intermediate space 15′ in the vertical direction V, which runs perpendicular to the lateral direction L1, only changes in the area of the first main surface 2A′, so that, for example, a lateral dimension a12 at a vertical distance from the second delimiting surface 2D′ is hardly larger than the dimension a11.

In the exemplary embodiments shown in FIGS. 6B to 6E, which can be produced by a method as explained in connection with FIGS. 3 to 5, the recess 4 is filled by the protective layer 7 only to a small extent in each case. The lateral dimensions a22, a32, a42 and a52 of the intermediate space 15 at a vertical distance from the second delimiting surface 2D are in each case significantly larger than the lateral dimension a12 of the comparative example. This creates more space for a contact means, which improves, for example, a thermal resistance of the optoelectronic component.

In the exemplary embodiment shown in FIG. 6B (cf. FIG. 3C), the protective layer 7 has an opening region 7A with a lateral dimension a21 that can correspond to the lateral dimension a11 of the comparative example. However, due to the larger lateral dimension a22, the thermal resistance of an optoelectronic component according to this exemplary embodiment is improved.

In the exemplary embodiment shown in FIG. 6C (cf. FIGS. 4C and 5B), the lateral dimension a31 of the opening region 7A is larger than in the comparative example shown in FIG. 6A. As a result, a contact area of the second semiconductor region 11 can be increased, thereby reducing a contact resistance and a forward voltage of the optoelectronic component.

In the exemplary embodiment shown in FIG. 6D (cf. FIG. 5C), the opening region 7A can be so large that the protective layer 7 extends from the first delimiting surfaces 2C only as far as the second delimiting surface 2D. The lateral dimension a41 of the opening region 7A is further enlarged compared to the exemplary embodiment shown in FIG. 6C. As a result, a contact area of the second semiconductor region 11 can be further increased, thereby further improving a contact resistance and a forward voltage of the optoelectronic component.

In the exemplary embodiment shown in FIG. 6E (cf. FIG. 5D), the protective layer 7 is delimited to the area of the junction 18 or the active zone 10, so that even more space is created for the contact means and the thermal resistance as well as the contact resistance and the forward voltage can be further improved compared to the exemplary embodiment of FIG. 6D.

With reference to FIG. 7, an exemplary embodiment of an optoelectronic component 1 is described, which can be produced, for example, by means of a method as described in connection with FIGS. 5A and 5D.

The optoelectronic component 1 comprises a structured region 2 which has a structured semiconductor body 3 with a first semiconductor region 9, an active zone 10 and a second semiconductor region 11 as well as structured layers 14A, 14B which are arranged on the semiconductor body 3. The structured layer 14A is, for example, a contact layer or a first electrical contact means that serves as a first electrode of the component 1. Furthermore, the structured layer 14B may be an insulating layer forming an electrical insulation between the first contact means and a second electrical contact means 16.

The structured region 2 has a first main surface 2A and a second main surface 2B, wherein the structured layers 14A, 14B are arranged on a surface 3A of the semiconductor body 3 which is located on a side of the semiconductor body 3 facing the first main surface 2A.

Furthermore, the structured region 2 has a plurality of first delimiting surfaces 2C and a second delimiting surface 2D, wherein the first delimiting surfaces 2C laterally delimit a recess 4 extending from the first main surface 2A into the structured region 2 or into the second semiconductor region 11, and the at least one second delimiting surface 2D delimits the recess 4 on a side facing the second main surface 2B. The recess 4 is thus closed on all sides. The second delimiting surface 2D is formed by a surface 11A of the second semiconductor region 11, which is arranged on a side facing the first main surface 2A. The surface 11A can be arranged substantially parallel to the second main surface 2B, i.e. within the scope of usual manufacturing tolerances. Furthermore, a part of each first delimiting surface 2C is formed by a surface 3C of the semiconductor body 3 arranged transversely to the first and second main surfaces 2A, 2B.

The recess 4 forms an intermediate space which is located between a raised partial region 12 and a lower partial region 13 of the structured region 2. The structured layers 14A, 14B, the first semiconductor region 9, the active zone 10 and a part of the second semiconductor region 11 are located in the raised partial region 12. A further part of the second semiconductor region 11 is located in the lower partial region 13.

The structured region 2 further comprises an electrically weakly conductive or non-conductive protective layer 7 arranged on the first delimiting surfaces 2C and covering the active zone 10 in the recess 4, wherein the first main surface 2A is uncovered by the protective layer 7. The uncovered main surface 2A can be obtained, for example, by structuring the second initial layer in a self-adjusting manner and structuring the first initial layer by means of the structured second initial layer, as described in connection with the various exemplary embodiments of a method. The protective layer 7 is essentially limited in its expansion to the region of the active zone 10, which can be achieved during production, for example, by long underetching of the second initial layer (cf. FIG. 5C). However, it is also possible for the protective layer 7 to have a design as described in connection with FIGS. 5B and 5C.

The protective layer 7 is a layer conformally deposited on the structured region 2 and containing an oxide such as Al2O3, Ta2O5, HfO2 or SiO2 or a nitride such as SiN or AlN. The protective layer 7 can be multilayered and comprise a combination of the aforementioned materials. The protective layer 7 is characterized, for example, by advantageous passivation properties.

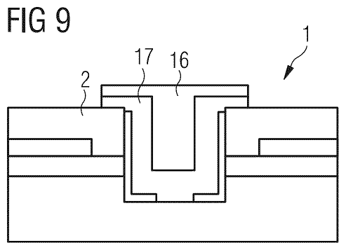

The protective layer 7 has an opening region 7A at the second delimiting surface 2D, in which the second electrical contact means 16 is arranged. The second electrical contact means 16 extends from the first main surface 2A through the recess 4 onto the second delimiting surface 2D and forms a second electrode of the optoelectronic component 1. Compared to the comparative example shown in FIG. 8, the second electrical contact means 16 has larger lateral dimensions a51, a52 (cf. FIGS. 6A and 6E), which results in a lower contact resistance, a lower forward voltage, a better thermal resistance, less component heating, a longer service life of the component 1 and a higher maximum operating current. In contrast to the comparative example, a current impression (indicated by arrows) is not only possible on the second delimiting surface 2D, but also on the first delimiting surfaces 2C. Overall, this improves the performance of the component 1.

These improved optoelectronic properties lead to a greater freedom in terms of component design. For example, the second contact means 16 can be designed with smaller lateral dimensions, which reduces light-absorbing surfaces. In return, the component can have additional reflective layers, making the component brighter overall.

FIG. 9 shows an exemplary embodiment of an optoelectronic component 1 which has a reflective layer 17 arranged on a side of the second contact means 16 facing the structured region 2 and which increases the brightness of the component 1.

The invention is not limited by the description based on the exemplary embodiments. Rather, the invention includes any new feature as well as any combination of features, which includes in particular any combination of features in the patent claims, even if this feature or combination itself is not explicitly stated in the patent claims or embodiments.

1-18. (canceled)

19. An optoelectronic component comprising:
a structured region comprising:
a semiconductor body comprising a first semiconductor region and a second semiconductor region, which have different conductivities;
a first main surface and a second main surface; and
at least one first delimiting surface and at least one second delimiting surface, wherein the at least one first delimiting surface laterally delimits a recess extending from the first main surface into the structured region, and the at least one second delimiting surface delimits the recess on a side facing the second main surface; and
an electrically weakly conductive or non-conductive protective layer, which is arranged on the at least one first delimiting surface and covers a junction between the first semiconductor region and the second semiconductor region in the recess,
wherein the first main surface is not covered by the protective layer and the protective layer does not adjoin any further protective layer on a side facing the junction and on a side facing away from the junction, and
wherein the protective layer is retracted from the first delimiting surface and the second delimiting surface and has a vertical distance, which is greater than zero, from the first delimiting surface and the second delimiting surface, or
wherein the protective layer has an L-shape in cross-section.

20. The optoelectronic component according to claim 19, wherein the protective layer is a layer conformally deposited on the structured region.

21. The optoelectronic component according to claim 19, wherein the protective layer contains an oxide or nitride.

22. The optoelectronic component according to claim 19, wherein the protective layer is retracted from the first main surface and has a vertical distance, which is greater than or equal to zero, from a plane of the first main surface.

23. The optoelectronic component according to claim 19, wherein the protective layer extends from the first delimiting surface to or onto the second delimiting surface and has a vertical distance therefrom which is equal to zero.

24. The optoelectronic component according to claim 19, wherein the protective layer has an opening region at the second delimiting surface, in which the second delimiting surface is uncovered by the protective layer.

25. The optoelectronic component according to claim 24, further comprising a first electrical contact means arranged in the opening region of the protective layer.

26. The optoelectronic component according to claim 25, further comprising a second electrical contact means arranged at the first main surface.

27. The optoelectronic component according to claim 19, wherein the second delimiting surface is formed by a surface of the second semiconductor region.

28. A method for producing the optoelectronic component according to claim 19, the method comprising:
providing the structured region;
generating a first initial layer for producing the electrically weakly conductive or non-conductive protective layer on the first main surface, the first delimiting surface and the second delimiting surface;
generating a second initial layer on the first initial layer for producing a further protective layer;
producing a structured second initial layer, wherein regions of the second initial layer which are arranged on the first main surface and regions, which are arranged on the second delimiting surface are removed; and
structuring the first initial layer by the structured second initial layer, wherein regions which are uncovered by the structured second initial layer are removed.

29. The method according to claim 28, wherein the second initial layer is produced thicker than the first initial layer.

30. The method according to claim 28, wherein the first initial layer is produced by one of the following methods: ALD, PECVD, or sputtering.

31. The method according to claim 28, wherein the second initial layer is produced from SiO2 or SiNx by chemical vapor deposition.

32. The method according to claim 28, wherein the second initial layer is structured by an anisotropic etching process.

33. The method according to claim 28, wherein the first initial layer is structured by a dry-chemical etching process, and the structured first initial layer is flush with the structured second initial layer.

34. The method according to claim 28, wherein the first initial layer is structured by a wet-chemical etching process, and the structured second initial layer is under-etched.

35. An optoelectronic component comprising:
a structured region comprising:
a semiconductor body comprising a first semiconductor region and a second semiconductor region, which have different conductivities;
a first main surface and a second main surface; and
at least one first delimiting surface and at least one second delimiting surface, wherein the at least one first delimiting surface laterally delimits a recess extending from the first main surface into the structured region, and the at least one second delimiting surface delimits the recess on a side facing the second main surface; and
an electrically weakly conductive or non-conductive protective layer, which is arranged on the at least one first delimiting surface and covers a junction between the first semiconductor region and the second semiconductor region in the recess,
wherein the first main surface is not covered by the protective layer, and
wherein a further protective layer, which is arranged on the protective layer, has a greater thickness than the protective layer arranged underneath and has a convexly curved surface on a side facing away from the structured region.
